(19) United States
(12) Patent Application Publication
(10) Pub. No.: US 2002/0045324 A1
(43) Pub. Date: Apr. 18, 2002

(54) METHOD FOR FORMING SHALLOW TRENCH ISOLATION

(76) Inventor: YEN-LIN DING, HSINCHU (TW)

Correspondence Address: J C Patents Inc, 4 Venture, Suite 250, Irvine, CA, 92618, US

(21) Appl. No.: 09/241,789

(22) Filed: Feb. 1, 1999

(30) Foreign Application Priority Data
Sep. 19, 1998 (TW) 87115639

(51) Int. Cl. H01L 21/8238; H01L 21/336; H01L 21/76

(52) U.S. Cl. 438/424; 438/221; 438/296; 438/426; 438/431

(57) ABSTRACT

A method for forming a shallow trench isolation structure is provided. A pad oxide and a mask layer are sequentially formed on a substrate, and then a shallow trench opening is formed. An insulation layer is formed on the substrate and filling the opening. After the insulation layer is planarized until the mask layer is exposed, a liner oxide is formed and the shallow trench isolation is densified simultaneously by thermal oxidation densification.

### BACKGROUND OF THE INVENTION

1. Field of the Invention

This invention relates in general to a manufacturing process for forming a device isolation structure, and more specifically relates to a manufacturing process for forming a shallow trench isolation structure.

2. Description of Related Art

In general, an integrated circuit consists of millions of metal-oxide semiconductor (MOS) transistors. In order to prevent neighboring transistors from shorting, a dielectric layer known as field oxide (FOX) is formed by local oxidation of silicon (LOCOS) to isolate the transistors. However, LOCOS still has many problems, such as mechanic stress and bird's beak encroachment. The bird's beak problem can not effectively isolate devices, especially in ultra small size device.

Conventionally, shallow trench isolation (STI) structure is widely used to isolate devices. Generally, a silicon nitride layer serving as a hard mask layer is formed on a substrate, and then a trench opening is patterned and formed by anisotropic etching. The opening is then filled with insulation material to form a device isolation structure by which the bird's beak problem of LOCOS is improved. For modem requirements of higher integration and thinner line width, the STI is an ideal and scaleable isolation technology.

FIGS. 1A through 1D schematically illustrate a conventional manufacturing process for forming a shallow trench isolation structure. Referring to FIG. 1A, a pad oxide 102 and a mask layer 104 are sequentially deposited on a substrate 100, and a shallow trench opening 106 is formed within the substrate 100. Therefore, there are sharp corners 114 and 114a on the top and bottom edges of the shallow trench opening 106. A liner oxide 108 is formed on the sidewall and bottom of the trench opening 106 by thermal oxidation at a temperature about 850° C. to 1100° C.

Referring to FIG. 1B, an insulation layer 110 is deposited on the substrate 100 and fills the opening 106 of the shallow trench 106. The insulation layer 110 is then densified for 10-30 minutes at about 1000° C.

Referring to FIG. 1C, the insulation layer is planarized until the surface of mask layer 104 is exposed to form shallow trench isolation 112.

Referring to FIG 1D, the mask layer 104 and the pad oxide 102 are removed sequentially, which complete the process for forming the shallow trench isolation structure. The following process for manufacturing semiconductor device is well known to those skilled in this field, which will not described herein.

According the description mentioned above, the liner oxide 108 is formed by thermal process and the shallow trench isolation is densified by thermal process. The thermal process causes mechanical stress, which creates defects in the substrate and damages the devices. Furthermore, if the curvature radii of the sharp corners at the top and bottom edges of the shallow trench are too small, high electric field and leakage current are easily produced. Therefore, the electric characteristics of the devices are influenced which causes electric instability and short problems.

### SUMMARY OF THE INVENTION

According to the foregoing description, an object of this invention is to provide a method for forming a shallow trench isolation structure by which the problem of devices damaged by mechanic stress due to the thermal process is solved.

Another object of this invention is to provide a method for forming a shallow trench isolation structure by which the problem of instability and shorts due to the presence of sharp corners at the top and bottom edges of trench are solved.

According to the objects mentioned above, a method for forming a shallow trench isolation structure is provided. First, a substrate is provided and a pad oxide and a mask layer are sequentially formed on the substrate. A shallow trench opening is formed within the pad oxide, the mask layer and the substrate. An insulation layer is formed on the substrate and fills the shallow trench opening. Simultaneously, a liner oxide is formed and the shallow trench isolation is densified by a thermal oxidation densification process. The mask layer and the pad oxide are removed and the shallow trench isolation structure is completed. The formation of the liner oxide and the densification of the shallow trench isolation are performed simultaneously by only one thermal process, so that the mechanic stress due to the thermal process is significantly reduced. Furthermore, while the liner oxide is formed the sharp corners are rounded by which the problems, such as leakage, instability and short, are improved.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings in which:

FIGS. 1A through 1D schematically illustrate a conventional manufacturing process for forming a shallow trench isolation structure; and

FIGS. 2A through 2E schematically illustrate a manufacturing process of a shallow trench isolation structure according to the preferred embodiment of this invention.

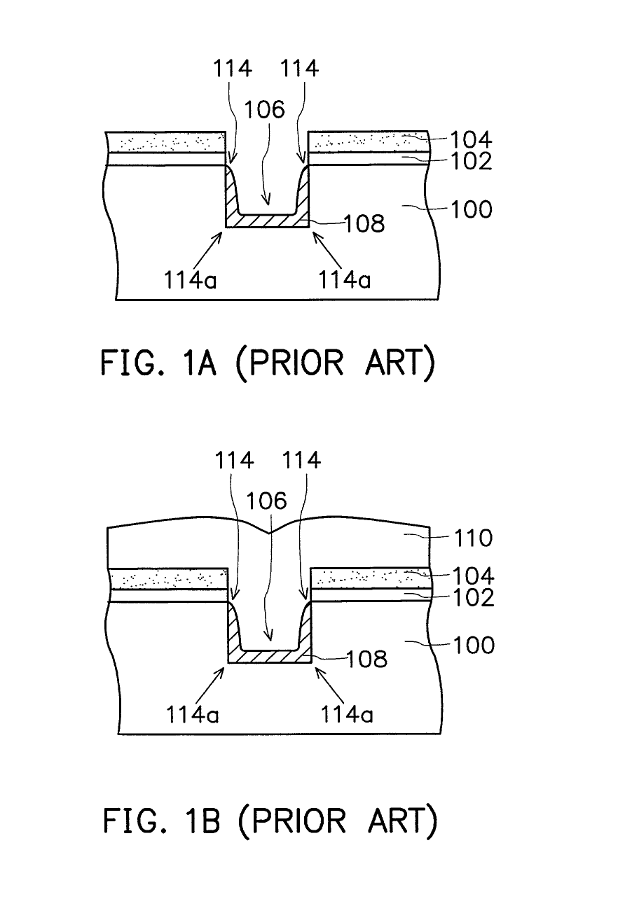

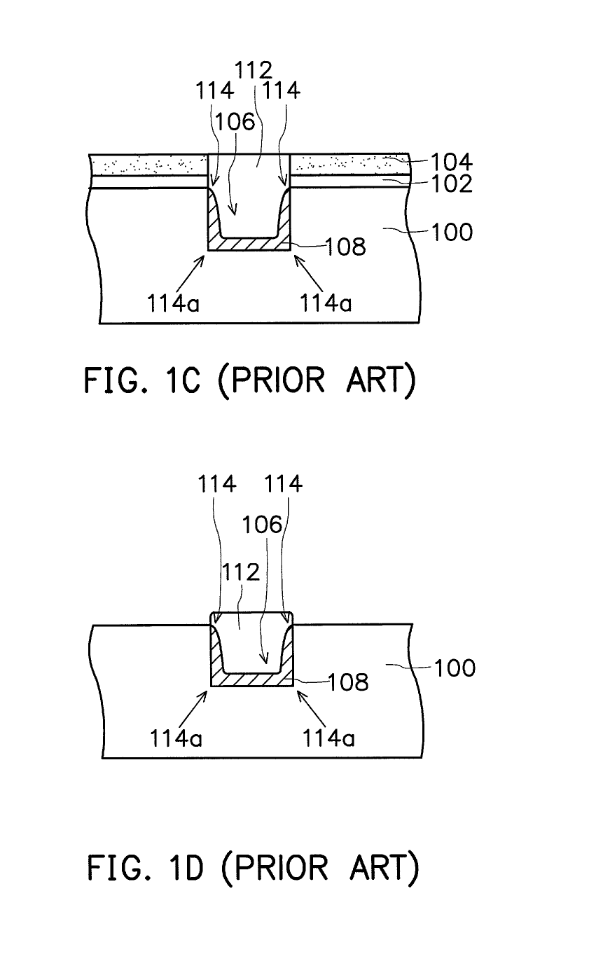

### DESCRIPTION OF THE PREFERRED EMBODIMENT

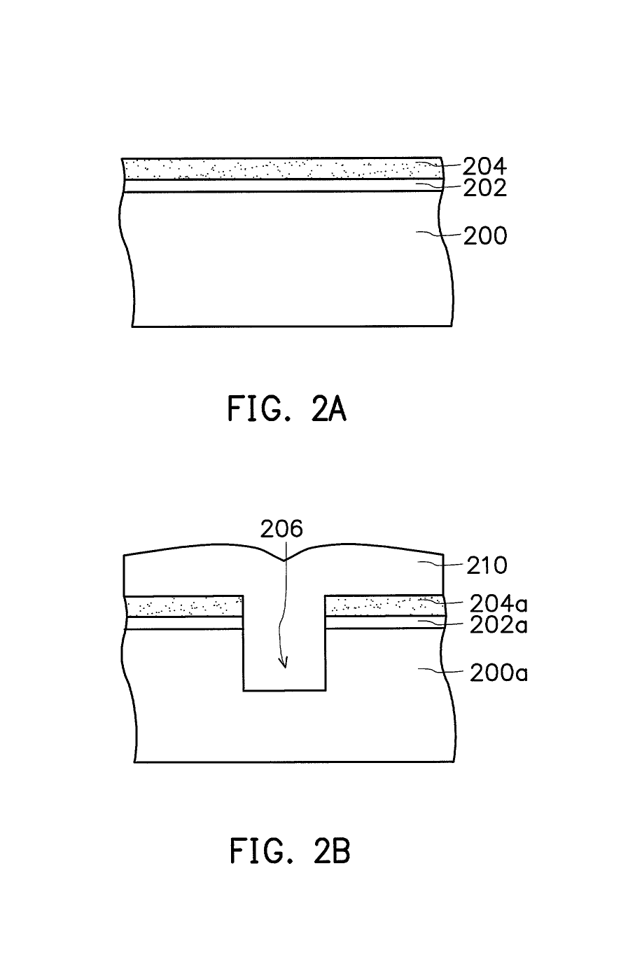

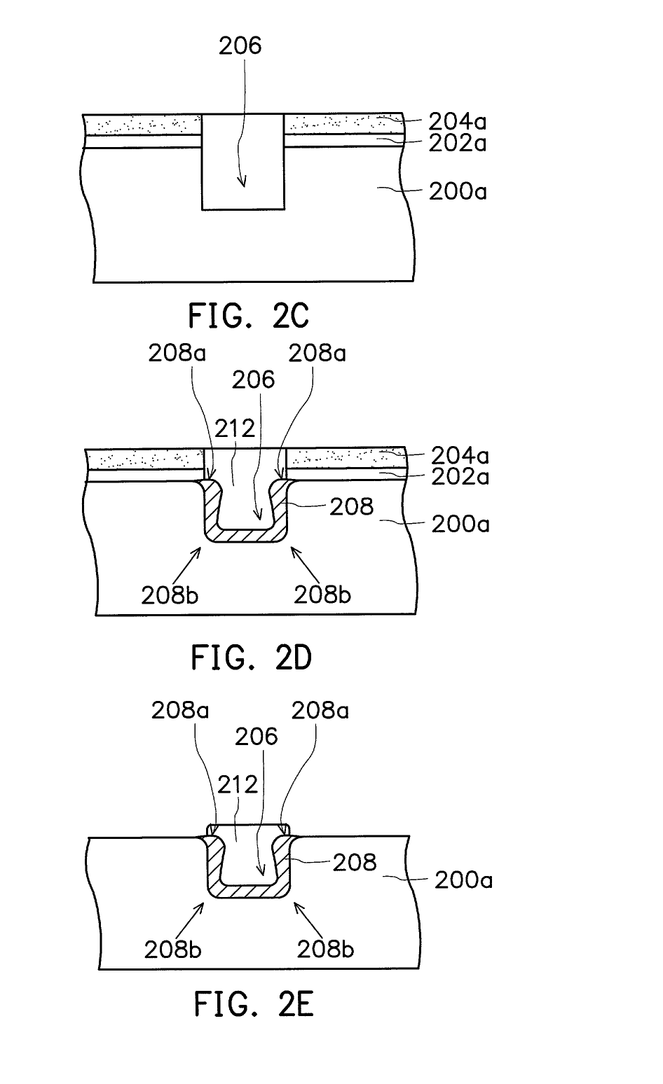

FIGS. 2A through 2E schematically illustrate a manufacturing process of a shallow trench isolation structure according to the preferred embodiment of this invention.

Referring to FIG. 2A, a pad oxide 202 and a mask layer 204 are sequentially formed on a provided semiconductor substrate 200. The pad oxide 202 is used to protect the substrate 200 from damage by subsequent etching processes. The mask layer 204, whose material is silicon nitride or the similar material, is formed by chemical vapor deposition (CVD) or any other similar method.

Referring to FIG. 2B, the mask layer 204, the pad oxide 202 and the substrate 200 are patterned and the patterned region is removed by a process such as anisotropic dry etching to form a mask layer 204a, a pad oxide 202a and a substrate 200a having a shallow trench opening 206. An insulation layer 210 is formed on the whole substrate 200a and fills the shallow trench opening 206. The insulation layer 210, whose material comprises silicon oxide, is formed by chemical vapor deposition (CVD), and atmosphere pressure CVD (APCVD) or low pressure CVD (LPCVD) is a preferred method.

Referring to FIG. 2C, the insulation layer 210 is planarized until the surface of the mask layer 204a is exposed. T he insulation layer 210 is planarized, for example, by chemical mechanical polishing (CMP) with slurry having high polishing selectivity until the surface of the insulation layer 210 is level with the mask layer 204a.

Referring to FIG. 2D, the formation of a liner oxide 208 and the densification of the shallow trench isolation 212 are completed at the same time by thermal oxidation densification. The thermal oxidation densification includes wet and dry oxidation. For example, the wet oxidation is performed at a temperature about 850° C. to 1180° C. within a chamber full of oxygen and moisture. The thickness of the liner oxide 208 is about 200Å to 1000Å.

The high temperature oxidation densification which is performed after the insulation layer is planarized is one of the significant features of this invention. During the high temperature oxidation densification, oxygen osmoses through the shallow trench isolation 212 and reacts with silicon at the boundary of the shallow trench isolation 212 and the substrat 200a to generate silicon oxide by which a liner oxide 208 is formed. The liner oxide 208 is capable of increasing the adhesion between the shallow trench isolation 212 and the substrate 200a

Referring to FIG. 2E, the mask layer 204a and the pad oxide 202a are removed and then the shallow trench isolation structure is completed. The method for removing the mask layer 204a includes wet and dry etching. For example, the wet etching uses a solution of hot phosphoric acid at about 150° C. to remove the mask layer 204a, and the dry etching uses a plasma consisting of SF₆, helium and oxygen to remove the mask layer 204a. The method for removing the pad oxide 202a, for example, uses wet etching with hydrofluoric acid as an etchant. After the shallow trench isolation structure is formed, the following processes for forming semiconductor devices, such as a field effect transistor (FET) and a metal oxide semiconductor (MOS), are performed. These processes are well known to those skilled in this field, and detailed descriptions are omitted here.

According to this invention, only one step of high temperature oxidation densification is used to simultaneously form the liner oxide 208 and the shallow trench isolation structure after the insulation layer is planarized. Therefore, the problem of substrate defect due to mechanical stress caused by multiple steps of high temperature oxidation densification in the conventional method is eliminated. Furthermore, because the liner oxide 208 is formed by oxygen osmosis, the sharp corner at the top and the bottom edges of the shallow trench isolation are rounded to form rounded corner 208a and 208b, respectively. Therefore, all problems caused by the sharp corners of the shallow trench isolation, such as leakage, electric instability and short, are solved.

According to the foregoing description, a feature of this invention is that high temperature oxidation densification is used only one time to simultaneously form the liner oxide and densify the shallow trench isolation. Therefore, no mechanical stress is present to damage the device. Another feature of this invention is that silicon is oxidized to form the liner oxide when the oxygen osmoses through the boundary of the shallow trench and the substrate during the high temperature oxidation densification process. Therefore, the sharp corners at the top and the bottom edges of the shallow trench isolation are rounded. Therefore, the leakage, electric instability and short problems caused by the sharp corners of the shallow trench isolation are solved.

Still another feature of this invention is that a simpler manufacturing process for forming a shallow trench isolation structure is provided, by which the cost is significantly reduced.

While the present invention has been described with a preferable embodiment, this description is not intended to limit our invention. Various modifications of the embodiment will be apparent to those skilled in the art. It is therefore contemplated that the appended claims will cover any such modifications or embodiments as fall within the true scope of the invention.

What claimed is:

1. A method for forming a shallow trench isolation structure, which is used to a provided substrate on which a pad oxide, a mask layer and a shallow trench opening are formed within the pad oxide, the mask layer and the substrate, the method comprising:
forming an insulation layer on the substrate and fills the shallow trench opening;
planarizing the insulation layer until the surface of the mask layer is exposed;
performing a thermal process;
removing the mask layer; and
removing the pad oxide.

2. The method of claim 1, wherein the thermal process consists of simultaneously forming a liner oxide and a shallow trench isolation.

3. The method of claim 1, wherein the thermal process includes wet oxidation.

4. The method of claim 1, wherein the thermal process is performed at a temperature about 850° C. to 1180° C.

5. The method of claim 1, wherein the thickness of the pad oxide is about 200Å to 1000Å.

6. The method of claim 1, wherein a method for planarizing the insulation layer includes chemical mechanic polishing (CMP).

7. The method of claim 6, wherein the method of CMP is performed with a slurry having high polishing selectivity.

8. The method of claim 1, wherein the material of the insulation layer is silicon oxide.

9. The method of claim 1, wherein the insulation layer is formed by atmosphere pressure chemical vapor deposition (APCVD).

10. The method of claim 1, wherein the insulation layer is formed by low pressure chemical vapor deposition (LPCVD).

11. The method of claim 1, wherein the mask layer is removed by wet etching.

12. The method of claim 11, wherein the wet etching is performed with hot phosphoric acid at a temperature about 150° C. to 180° C.

13. The method of claim 1, wherein the mask layer is removed by dry etching.

14. The method of claim 13, wherein the dry etching is performed with a plasma consisting of SF₆, helium and oxygen.

15. The method of claim 1, wherein the pad oxide is removed by wet etching.

16. The method of claim 15, wherein the wet etching is performed with an etchant of hydrofluoric acid.

17. A method for forming a shallow trench isolation structure, comprising:
providing a substrate on which a pad oxide and mask layer are formed;
patterning the mask layer, the pad oxide and the substrate to form a shallow trench opening;
forming an insulation layer on the substrate and filling the shallow trench opening;
planarizing the insulation layer until the surface of the mask layer is exposed;
performing a densification process; and
removing the mask layer and the pad oxide.

18. The method of claim 17, wherein the material of the mask layer is silicon nitride.

19. The method of claim 17, wherein the densification process consists of forming a liner oxide between the substrate and the insulation layer.

20. The method of claim 19, wherein the thickness of the liner oxide is about 200Å to 1000Å.

21. The method of claim 17, wherein the densification is performed at a temperature about 850° C. to 1180° C.
